(19) United States
(12) Patent Application Publication
(10) Pub. No.: US 2013/0183225 A1
(43) Pub. Date: Jul. 18, 2013

(54) CRYSTAL GROWTH USING NON-THERMAL ATMOSPHERIC PRESSURE PLASMAS

(71) Applicant: The Regents of the University of California, Oakland, CA (US)

(72) Inventors: Paul Von Dollen, Santa Barbara, CA (US); James S. Speck, Goleta, CA (US); Siddha Pimputkar, Santa Barbara, CA (US)

(73) Assignee: THE REGENTS OF THE UNIVERSITY OF CALIFORNIA, Oakland, CA (US)

(21) Appl. No.: 13/744,854

(22) Filed: Jan. 18, 2013

Related U.S. Application Data
(60) Provisional application No. 61/588,028, filed on Jan. 18, 2012.

(51) Int. Cl. C30B 30/02; C30B 9/00; C30B 29/40

(52) U.S. Cl. CPC C30B 30/02; C30B 29/403; C30B 9/00
USPC 423/409; 204/178; 422/186; 422/186.04

(57) ABSTRACT

A method and apparatus for bulk crystal growth using non-thermal atmospheric pressure plasmas. This method and apparatus pertains to growth of any compound crystal involving one or more crystal components in a liquid phase (also known as the melt or solution), in communication with a non-thermal atmospheric pressure plasma source comprised of one or more other crystal components.

### CROSS REFERENCE TO RELATED APPLICATIONS

This application claims the benefit under 35 U.S.C. Section 119(e) of U.S. Provisional Patent Application Ser. No. 61/588,028, filed on Jan. 18, 2012, by Paul Von Dollen, James S. Speck, and Siddha Pimputkar, and entitled “CRYSTAL GROWTH USING NON-THERMAL ATMOSPHERIC PRESSURE PLASMAS,” attorneys' docket number 30794.444-US-P1 (2012-456-1), which application is incorporated by reference herein.

This application is related to the following co-pending and commonly-assigned patent applications:

P.C.T. International Patent Application Serial No. PCT/US12/04675, filed on Jul. 13, 2012, by Siddha Pimputkar, Shuji Nakamura and James S. Speck, entitled “USE OF GROUP-III NITRIDE CRYSTALS GROWN USING A FLUX METHOD AS SEEDS FOR AMMONOTHERMAL GROWTH OF A GROUP-III NITRIDE CRYSTAL,” attorneys' docket number 30794.419-WO-U1 (2012-020-2), which application claims the benefit under 35 U.S.C. Section 119(e) of U.S. Provisional Patent Application Ser. No. 61/507,170, filed on Jul. 13, 2011, by Siddha Pimputkar and Shuji Nakamura, entitled “USE OF GROUP-III NITRIDE CRYSTALS GROWN USING A FLUX METHOD AS SEEDS FOR AMMONOTHERMAL GROWTH OF A GROUP-III NITRIDE CRYSTAL,” attorneys' docket number 30794.419-US-P1 (2012-020-1), and U.S. Provisional Patent Application Ser. No. 61/507,187, filed on Jul. 13, 2011, by Siddha Pimputkar and James S. Speck, entitled “METHOD OF GROWING A BULK GROUP-III NITRIDE CRYSTAL USING A FLUX BASED METHOD THROUGH PREPARING THE FLUX PRIOR TO BRINGING IT IN CONTACT WITH THE GROWING CRYSTAL,” attorneys' docket number 30794.421-US-P1 (2012-022);

P.C.T. International Patent Application Serial No. PCT/US12/04676, filed on Jul. 13, 2012, by Siddha Pimputkar, Shuji Nakamura and James S. Speck, entitled “METHOD FOR IMPROVING THE TRANSPARENCY AND QUALITY OF GROUP-III NITRIDE CRYSTALS AMMONOTHERMALLY GROWN IN A HIGH PURITY GROWTH ENVIRONMENT,” attorneys' docket number 30794.422-W0-U1 (2012-023-2), which application claims the benefit under 35 U.S.C. Section 119(e) of U.S. Provisional Patent Application Ser. No. 61/507,212, filed on Jul. 13, 2011, by Siddha Pimputkar and Shuji Nakamura, entitled “HIGHER PURITY GROWTH ENVIRONMENT FOR THE AMMONOTHERMAL GROWTH OF GROUP-III NITRIDES,” attorneys' docket number 30794.422-US-P1 (2012-023-1); U.S. Provisional Patent Application Ser. No. 61/551,835, filed on Oct. 26, 2011, by Siddha Pimputkar, Shuji Nakamura, and James S. Speck, entitled “USE OF BORON TO IMPROVE THE TRANSPARENCY OF AMMONOTHERMALLY GROWN GROUP-III NITRIDE CRYSTALS,” attorneys' docket number 30794.438-US-P1 (2012-248-1); and U.S. Provisional Patent Application Ser. No. 61/552,276, filed on Oct. 27, 2011, by Siddha Pimputkar, Shuji Nakamura, and James S. Speck, entitled “USE OF SEMIPOLAR SEED CRYSTAL GROWTH SURFACE TO IMPROVE THE QUALITY OF AN AMMONOTHERMALLY GROWN GROUP-III NITRIDE CRYSTAL,” attorneys' docket number 30794.439-US-P1 (2012-249-1);

U.S. Utility patent application Ser. No. 13/659,389, filed on Oct. 24, 2012, by Siddha Pimputkar, Paul von Dollen, James S. Speck, and Shuji Nakamura, and entitled “USE OF ALKALINE-EARTH METALS TO REDUCE IMPURITY INCORPORATION INTO A GROUP-III NITRIDE CRYSTAL GROWN USING THE AMMONOTHERMAL METHOD,” attorneys' docket number 30794.433-US-U1 (2012-236-2), and P.C.T. International Patent Application Serial No. PCT/US12/61628, filed on Oct. 24, 2012, by Siddha Pimputkar, Paul von Dollen, James S. Speck, and Shuji Nakamura, entitled “USE OF ALKALINE-EARTH METALS TO REDUCE IMPURITY INCORPORATION INTO A GROUP-III NITRIDE CRYSTAL GROWN USING THE AMMONOTHERMAL METHOD” attorneys' docket number 30794.433-WO-U1 (2012-236-2), both of which applications claim the benefit under 35 U.S.C. Section 119(e) of U.S. Provisional Patent Application Ser. No. 61/550,742, filed on Oct. 24, 2011, by Siddha Pimputkar, Paul von Dollen, James S. Speck, and Shuji Nakamura, and entitled “USE OF ALKALINE-EARTH METALS TO REDUCE IMPURITY INCORPORATION INTO A GROUP-III NITRIDE CRYSTAL GROWN USING THE AMMONOTHERMAL METHOD,” attorneys' docket number 30794.433-US-P1 (2012-236-1);

U.S. Provisional Patent Application Ser. No. 61/603,143, filed on Feb. 24, 2012, by Paul von Dollen, and entitled “ELECTROMAGNETIC MIXING FOR NITRIDE CRYSTAL GROWTH,” attorneys' docket number 30794.447-US-P1 (2012-506-1); and

U.S. Provisional Patent Application Ser. No. 61/622,232, filed on Apr. 10, 2012, by Siddha Pimputkar, Paul Von Dollen, Shuji Nakamura, and James S. Speck, and entitled “APPARATUS USED FOR THE GROWTH OF GROUP-III NITRIDE CRYSTALS UTILIZING CARBON FIBER CONTAINING MATERIALS AND GROUP-III NITRIDE GROWN THEREWITH,” attorneys' docket number 30794.451-US-P1 (2012-654-1);

all of which applications are incorporated by reference herein.

### BACKGROUND OF THE INVENTION

1. Field of the Invention

This invention relates to a method for crystal growth using non-thermal atmospheric pressure plasmas.

2. Description of the Related Art

There is a need and a desire for optoelectronic devices (LEDs, lasers, high frequency/high power switches, etc.) of increased performance at reduced cost. Group III-nitrides (AlN, InN, GaN, etc.) are well suited for these applications, but current device performance/cost ratios do not facilitate widespread market penetration. In particular, the performance/cost ratio for GaN is significantly hampered by heteroepitaxial fabrication techniques on non-native substrates (Al₂O₃Si, SiC, etc.). Homoepitaxy on native GaN substrates represents a significant opportunity for improved device performance at reduced cost.

Native GaN substrates can be derived through wafering or slicing bulk GaN boules, as is the case with silicon, GaAs, GaP, etc. However, bulk GaN crystal growth at industrially relevant scale (both cross-sectional area as well as realized growth rates) has mostly eluded research and development efforts. 2″-class bulk GaN wafers are beginning to reach commercialization, but they are currently too costly for large-volume applications such as LEDs. Furthermore, it is unclear if state-of-the-art commercialized growth techniques (ammonothermal, hydride vapor phase epitaxy (HVPE), etc.) can be feasibly and economically scaled to next generation 4″, 6″, etc., wafer platforms. Clear motivation and market opportunity exists for development of bulk GaN crystal growth at decreased cost and larger cross-sectional areas.

Thus, there is a need in the art for improved methods of crystal growth. The present invention satisfies these needs.

### SUMMARY OF THE INVENTION

The present invention discloses a method and apparatus for bulk crystal growth using non-thermal atmospheric pressure plasmas. Specifically, this invention pertains to growth of any compound crystal involving one or more crystal components in a liquid phase (also known as a fluid, melt or solution), in communication with a non-thermal atmospheric pressure plasma source comprised of one or more other crystal components.

The compound crystal may comprise a Group-III nitride crystal, and the Group-III nitride crystal is grown using a flux-based growth, wherein the flux-based growth includes: (1) a solution comprised of at least one Group-III metal contained within a vessel or reactor, wherein the solution and one or more surfaces of a seed upon which the Group-III nitride crystal is grown are brought into contact; and (2) a source of at least one component for the growth of the Group-III nitride crystal is a non-thermal atmospheric pressure plasma introduced to the vessel or reactor.

The non-thermal atmospheric pressure plasma may be operated at a pressure between 0.5 atmospheres and 3 atmospheres, and may be the source for nitrogen at atmospheric pressure for use in the growth of the Group-III nitride crystal.

The non-thermal atmospheric pressure plasma may comprise one or more directed streams in communication with the solution, including: (1) where the non-thermal atmospheric pressure plasma is incident above a surface of the solution; (2) where the non-thermal atmospheric pressure plasma is submerged within the solution, and (3) where the non-thermal atmospheric pressure plasma is introduced within the solution by a conduit.

When the non-thermal atmospheric pressure plasma is introduced within the solution by a conduit, the conduit may include pores that introduce only a portion of the non-thermal atmospheric pressure plasma to the Group-III nitride crystal's growth interface. Moreover, the non-thermal atmospheric pressure plasma's interaction with the solution may be modulated by altering the conduit's configuration.

The non-thermal atmospheric pressure plasma and the Group-III nitride crystal's growth interface may separated by a distance that promotes the Group-III nitride crystal's growth while preventing disruption of the Group-III nitride crystal's growth interface.

The solution may comprise an electrode for a source of the non-thermal atmospheric pressure plasma.

### BRIEF DESCRIPTION OF THE DRAWINGS

Referring now to the drawings in which like reference numbers represent corresponding parts throughout:

FIG. 1 is a general schematic of a proposed flux-based crystal growth method according to the present invention.

FIG. 2 illustrates a preferred embodiment A with plasma directly incident on a crystal growth solution surface.

FIG. 3 illustrates a preferred embodiment B with plasma within a crystal growth solution.

FIG. 4 illustrates a preferred embodiment C with plasma effluent introduced to a crystal growth interface through a conduit with pores.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Technical Description

The present invention involves bulk crystal growth of a compound involving a liquid phase (also known as a fluid, melt or solution) in communication with a non-thermal atmospheric pressure plasma source. The liquid phase can be comprised of one crystal component (e.g., Ga, etc.) or one or more crystal components (e.g., Ga and In, Ga and Al, Ga and Si, etc.) along with one or more other components present to facilitate crystal forming reactions, suppress deleterious reactions and/or modify solution characteristics (viscosity, density, conductivity, melting point, etc.). Similarly, the non-thermal atmospheric pressure plasma source can be comprised of one or more other crystal components.

The already established “sodium flux” (“Na Flux”) method can be thought of as a starting point for further enhancement of crystal growth (lower pressure, faster growth rates, etc.) by addition of a plasma source of one or more crystal components. Bulk GaN crystals are currently grown at the research scale using the sodium flux method of GaN crystal growth, where a melt of Ga and Na is exposed to a nitrogen atmosphere to form solid GaN.

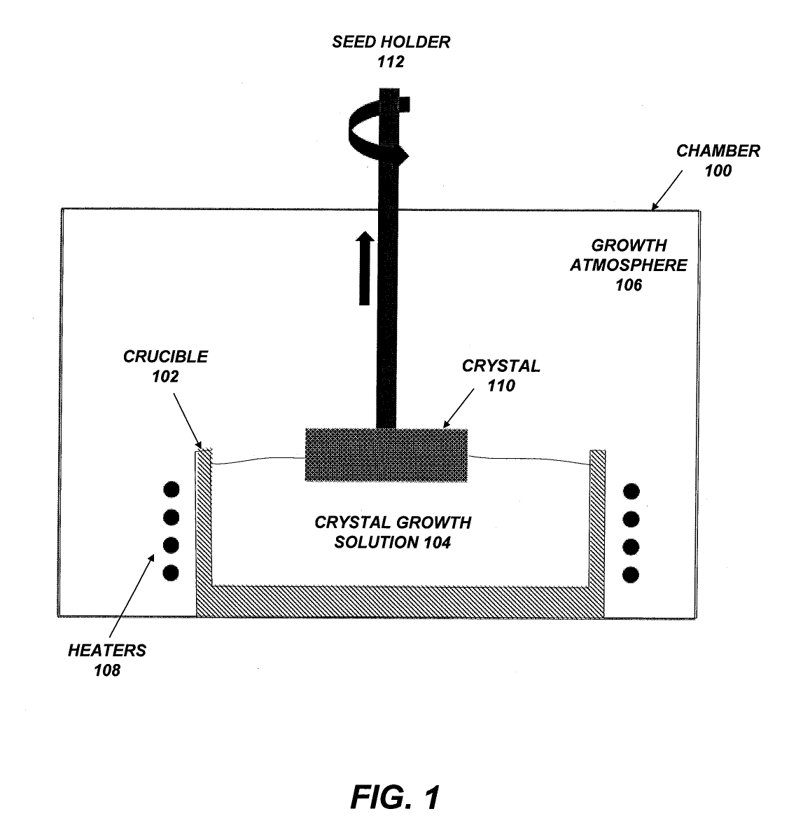

FIG. 1 is a schematic that illustrates a method and apparatus used for growing a compound crystal, such as a Group-III nitride crystal, using a flux-based growth method.

In one embodiment of the present invention, the flux-based crystal growth method makes use of a reaction vessel or chamber 100 (which may be open or closed) having a refractory crucible 102, comprised of a non-reactive material such as boron nitride or alumina, that contains a liquid, fluid or melt that is a crystal growth solution 104.

The solution 104 is comprised of at least one Group-III metal, such as Al, Ga and/or In, and at least one alkali metal, such as Na. In the preferred embodiment, the solution 104 is a mixture of predominantly containing sodium (>50 mol %) with the remainder gallium, as this alloy range is known to have a high nitrogen solubility and facilitates high crystal growth rates >30 μm/hr. The solution 104 may contain any number of additional elements, compounds, or molecules to modify growth characteristics and crystal properties, such as B, Li, K, Rb, Cs, Be, Mg, Ca, Sr, Ba, Sr, C, Bi, Sb, Sn, Be, Si, Ge, Zn, P and/or N.

Additionally, the chamber 100 contains a growth atmosphere 106 in which the solution 104 is placed, that can be a nitrogen-containing atmosphere 106, including, but not limited to, atomic nitrogen N, diatomic N₂, ammonia NH₃, hydrazine N₂H₆, or an atmosphere 106 with only trace amounts of nitrogen present, for example, an atmosphere comprised mainly of hydrogen, argon, etc. The atmosphere 106 may be at vacuum, or may have a pressure greater than approximately 1 atmosphere (atm) and up to approximately 1000 atm.

The crucible 102 may include one or more heaters 108 so that the solution 104 may be heated and then held at one or more set temperatures, and one or more temperature gradients may be established within the chamber 100. Heating 108 may be accomplished through inductive coupling to the conductive solution 104. Preferably, the crucible 102, solution 104, seed 110 and seed holder 112 are contained within a reactor vessel 100 at a temperature above the solution 104 melting point. In one embodiment, the solution 104 is held at a temperature greater than approximately 200° C. and below approximately 1200° C. during growth.

The chemical potential of the solution 104 may be raised or lowered with respect to vacuum through the use of a power source (not shown) operating at arbitrary frequencies (f>=0 Hz) and voltages. The solution 104 and atmosphere 106 in which it has been placed may be subject to electromagnetic fields, both static and/or dynamic.

A seed crystal 110 upon which the compound crystal is grown is affixed to a seed holder 112, which allows movement, rotation and retraction during the growth process, by mechanical or by other means. For example, the seed 110 can be affixed to the seed holder 112 using ceramic cement or metals such as Ag, Au, Pd, Pt, etc., or blends such as Ag/Pd, Au/Pd, etc., wherein the metals are introduced as suspensions in a viscoelastic carrier and comprise pastes. After affixing the seed crystal 110, the bond must be formed and the binder removed by heating the seed holder 112 and seed 110.

Once the chamber 100 containing the solution 104 has been adequately prepared, one or more surfaces of the seed crystal 110 can be brought into contact with the solution 104, or the solution 104 can be brought into contact with one or more surfaces of the seed 110, wherein the seed 110 is at least partially exposed to the atmosphere 106. Once the seed 110 and the solution 104 are brought into contact, the seed 110 and/or the solution 104 may be subject to mechanical movements of the seed holder 112, such as mixing, stirring or agitating, to shorten the time required to saturate the solution 104 with nitrogen. Mixing may also be accomplished through inductive coupling to the conductive solution 104.

In a preferred embodiment, the seed 110 is a Group-III nitride crystal, such as GaN, etc., and may be a single crystal or a polycrystal. However, this should not be seen as limiting for this invention. This invention specifically includes growing a Group-III nitride crystal on an arbitrary material, wherein the seed 110 may be an amorphous solid, a polymer containing material, a metal, a metal alloy, a semiconductor, a ceramic, a non-crystalline solid, a poly-crystalline material, an electronic device, an optoelectronic device.

When the seed 110 is a Group-III nitride crystal, it may have one or more facets exposed, including polar, nonpolar and semipolar planes. For example, the Group-III nitride seed crystal 110 may have a large polar c-plane {0001} facet or a {0001} approaching facet exposed; or the Group-III nitride seed crystal 110 may have a large nonpolar m-plane {10-10} facet or a {10-10} approaching facet exposed; or the Group-III nitride seed crystal 110 may have a large semipolar {10-11} facet or a {10-11} approaching facet exposed; or the Group-III nitride seed crystal 110 may have a large nonpolar a-plane {11-20} facet or a {11-20} approaching facet exposed.

The flux method that is used to coat the seed 110 and form a resulting Group-III nitride crystal on the seed 110 is based on evaporation from the solution 104, but may also include a solid source containing Group-III and/or alkali metals, which results in the formation of a layer of Group-III and alkali metal on the surfaces of the seed 110. In one example, the flux method used to coat the seed 110 and form the Group-III nitride crystal on the seed 110 is based on bringing the seed 110 into contact with the solution 104, intermittently or otherwise, by means of dripping and/or flowing the solution 104 over one or more surfaces of the seed 110. In another example, the flux method used to coat the seed 110 and form the Group-III nitride crystal on the seed 110 involves submersing or submerging the seed 110 within the solution 104 and placing one facet of the seed 110 within some specified distance, such as 5 mm, of the interface between the solution 104 and the atmosphere 106. Further, the seed 110 may be rotated and/or moved on a continuous or intermittent basis using the seed holder 112.

The resulting Group-III nitride crystal that is grown on the seed 110 is characterized as AlₓB_{y}Ga_{z}In_{(1-x-y-z)}N, where 0<=x<=1, 0<=y<=1, 0<=z<=1, and x+y+z<=1. For example, the Group-III nitride crystal may be AN, GaN, InN, AlGaN, AlInN, InGaN, etc. In another example, the Group-III nitride crystal may be at least 2 inches in length when measuring along at least one direction. The Group-III nitride crystal may also have layers with different compositions, and the Group-III nitride crystal may have layers with different structural, electronic, optical, and/or magnetic properties.

Thus, FIG. 1 shows a general schematic for flux-based crystal growth where a seed crystal 110 is introduced to the free solution 104 surface and can be rotated as well as raised or lowered by the seed holder 112. GaN will crystallize from a pure Ga melt 104 exposed to a nitrogen-containing atmosphere 106, but the growth rate is negligible unless high temperatures and pressures are used. Theoretically, the Na promotes dissociation of the N₂ gas molecule, and the Na/Ga solution 104 exhibits a relatively large equilibrium dissolved atomic nitrogen concentration. The driving force for solid GaN growth is provided by introducing a temperature gradient within the solution 104, and growth rates as high as ˜30 μm/hr are realized using the flux-based growth method. However, even when using Na, pressures greater than 30 atmospheres (atm) and temperatures ˜800° C. are necessary to realize appreciable crystal 110 growth rates.

In the present invention, the use of a plasma phase circumvents the requirement for high pressures and temperatures by providing atomic nitrogen at atmospheric pressure. It may be that Na or another flux agent (Sn, Bi, Pb, etc.) is still necessary to modify molten Ga properties to allow proper crystal growth, but it is also possible that bulk GaN boule growth can be realized using atmospheric plasmas with a pure Ga melt.

A “non-thermal” plasma is one in which the plasma constituents (free electrons, ions, neutral gas molecules, atomic gas species, etc.) do not reach thermal equilibrium. Rather, the electrons increase in kinetic energy (temperature) while the heavier atomic, molecular and ionic species gain enough energy to promote dissociation and excitation, but do not greatly increase in temperature. For example, typical thermal equilibrium conditions in a plasma involve temperatures for both gas and electrons of ˜10,000° K while a non-thermal plasma can operate at ˜500-800° K. A “non-thermal” plasma is advantageous to crystal growth in three main ways: (1) reduced disruption of the growth interface by heating; (2) reduced reactor design requirements due to lower temperatures; and (3) reduced disruption of the growth interface by high gas flow rates necessary for cooling of the thermal equilibrium plasma source.

An atmospheric pressure plasma (APP) is one in which plasma formation occurs at or near atmospheric pressure (˜1 bar or 760 Torr). Non-thermal plasmas are routinely used in molecular beam epitaxy (MBE) and metal-organic chemical vapor deposition (MOCVD) techniques to increase reactive species concentrations and plasmas have also been used for bulk GaN growth. Some improvements in growth rates using various configurations have been reported and described. However, these plasmas are typically generated at sub-atmospheric pressures. Atmospheric plasma operation is advantageous from a standpoint of reactor design since no special steps need to be taken to seal vacuum (sub-atmospheric) conditions. In addition, higher pressure plasma implies higher species concentrations, advantageous for crystal growth.

Non-thermal atmospheric pressure plasmas (NTAP) can be generated using a variety of methods including: dielectric barrier discharge, radio-frequency (RF) discharge, hollow-cathode discharge, pulsed direct current (DC) discharge and microwave discharge. The plasma is created within an inert carrier gas such as helium or argon containing some amount of the reactive gas (e.g., oxygen or nitrogen). Non-thermal atmospheric plasmas can also be formed using air (78% nitrogen) in some cases.

Ease of plasma creation and plasma stability are both related to gas composition and flow rates. For instance, typical total flow rates for ˜1-10 vol % nitrogen in helium or argon are ˜10-20 SLPM (standard liters per minute) to provide adequate plasma stability and provide cooling for plasma source components.

In particular, non-thermal atmospheric pressure plasmas produced using RF discharges are reported to have high concentrations of active atomic species such as N and O. High active species concentrations in the plasma will lead to high species fluxes which are beneficial to achieving high crystal growth rates and high crystal quality. For the purposes of this invention, it is desirable to maximize the active species concentration in the plasma.

Even though typical gas flow rates are much reduced for a non-thermal plasma (˜10-20 SLPM vs. ˜100 SLPM for a thermal equilibrium plasma source), they may still be mechanically disruptive to crystal growth. Instead of plasma generation within a gas phase incident on a melt or crystal growth surface, non-thermal atmospheric plasmas can also be formed within a liquid phase. These so-called “in-liquid” or submerged plasmas involve reduced flow rates of ˜0.5 SLPM or less. The (submerged, non-thermal, atmospheric pressure) plasma can be formed in a self-contained manner or in a configuration where the liquid itself comprises one of the electrodes. A low gas flow rate submerged (either self-contained or liquid electrode) plasma may be advantageous from a crystal growth standpoint by virtue of maximizing the surface area for interaction between the plasma and the crystal growth solution while minimizing disruption of the liquid with low plasma gas flow rates. This basic configuration is denoted as SNAP for Submerged, Non-thermal, Atmospheric Pressure plasma.

Still another configuration involves selective introduction of plasma gas or constituents into the solution without subjecting the crystal growth interface to the full plasma gas flow rate. The plasma source can be operated in a submerged fashion directly into a conduit or pipe, or the effluent from a non-submerged plasma source can be directed below the melt surface by a suitable conduit or pipe. Transverse pores or small holes in the conduit sidewalls could allow introduction of just a portion of the plasma to the solution while the main plasma flow is conducted out of the crystal growth interface region. The amount and location of plasma interaction with the solution can be readily modulated by changing pore and conduit size, shape, flow rate, etc.

Crystal growth can be carried out by spontaneous nucleation, heteroepitaxial seeding (e.g., GaN grown on sapphire, etc.) or homoepitaxial seeding (GaN grown on GaN). The seed can be introduced to the top (free surface) of the melt or submerged below the melt. The top-seeded configuration has several advantages including: (1) facilitation of continuous or semi-continuous crystal growth through retraction of the grown crystal; (2) suppression of volatile flux and crystal components by substantially covering the free solution surface with the seed crystal; and (3) opportunity to rotate the seed crystal during growth to modulate convection and mass transport (diffusion boundary layer) conditions to enhance growth.

The plasma source can be a directed stream onto the liquid surface or a broader-area array of many small streams over a larger liquid surface. Likewise, for the SNAP configuration, the plasma source can comprise one or many individual plasma streams to maximize the active species flux to the growth interface and optimize crystal growth.

Due to the fact that the driving force for crystallization is provided externally by the plasma source, the crystal growth process can be carried out isothermally, or a temperature gradient can be created to provide additional driving force for growth, if desired. Process heating and control can be accomplished externally, where a sealed or largely sealed reaction vessel is placed within a hot zone formed by resistively heated elements, convective flow of hot gases, inductive coupling to a heating susceptor, etc. Process heating and control can also be accomplished using heating elements located within a sealed or largely sealed reaction vessel where the heat is provided by resistive elements, inductive coupling to a susceptor, or directly to the growth solution, etc. The process temperature must be greater than the melting point of the crystal growth solution, but can be adjusted to improve crystal growth rate, crystal quality, stable crystal orientation, etc. It is likely the preferred process temperature is equal to or greater than 800° C. or greater than 1000° C.

### Preferred Embodiments

Three preferred embodiments for the growth of GaN bulk crystals are described below; the most advantageous method will depend on the extent to which gas flow rates disrupt the crystal growth process and other factors. In all cases, the preferred embodiments involve homoepitaxial top seeding using a previously created seed crystal 110. In the preferred embodiments, the solution 104 is a mixture of predominantly containing sodium (>50 mol %) with the remainder gallium, as this alloy range is known to have a high nitrogen solubility and facilitates high crystal growth rates >30 μm/hr.

In these embodiments, a source of at least one component for the growth of the Group-III nitride crystal is a non-thermal atmospheric pressure plasma introduced to the vessel 100. For example, the non-thermal atmospheric pressure plasma may be the source for atomic nitrogen at atmospheric pressure, wherein the non-thermal atmospheric pressure plasma is one or more directed streams in communication with the solution.

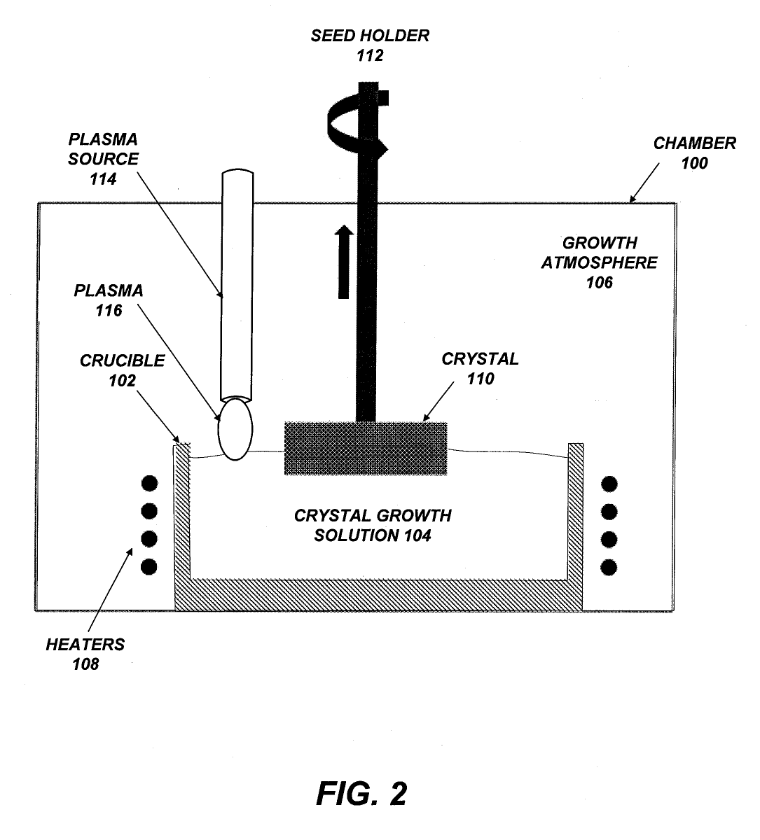

In preferred embodiment A shown in FIG. 2, an RF plasma source 114 is incident above a surface of the solution 104, such that the plasma 116 effluent stream is incident on the surface of the solution 104 adjacent to the seed 110 and seed holder 112. The plasma 116 is a mixture of He (or other inert gas such as Ar, Xe, Ne, etc.) and N₂ gas with a total flow rate between 0 and 20 SLPM. Preferably, the plasma 116 is operated at a pressure between 0.5 atmospheres and 3 atmospheres.

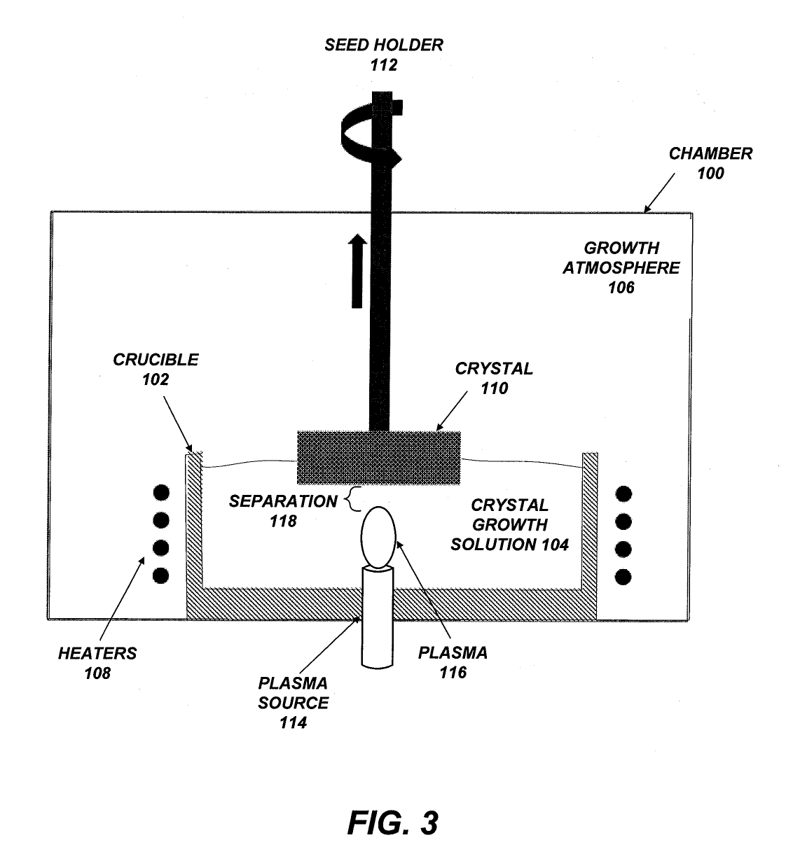

In preferred embodiment B shown in FIG. 3, the so-called SNAP configuration, the plasma source 114 is submerged in the solution 104, such that the plasma 116 effluent is introduced into and submerged within the solution 104 adjacent to the likewise submerged crystal 110 growth interface (i.e., surface). The conductive solution 104 may act as one electrode for the RF or pulsed DC plasma source 114 discharge. The plasma 116 gas is a mixture of He and N₂ or pure N₂. The total gas flow rate in this embodiment is less than 0.5 SLPM and preferably low enough so that major bubbling or disruption of the crystal 110 growth interface does not occur. The plasma 116 zone and crystal 110 growth interface are separated by an optimum interlayer distance labeled as separation 118, wherein the separation 118 distance between the plasma 116 and seed 110 growth interface can likewise be adjusted to promote growth (shorter mass transport distance) while preventing disruption of the seed 110 growth interface.

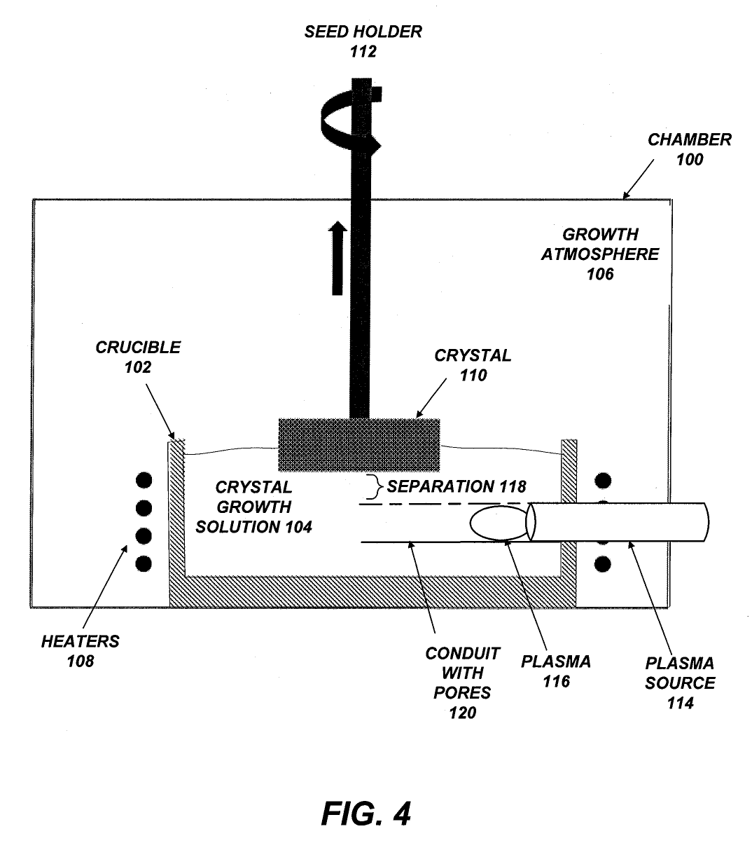

In preferred embodiment C shown in FIG. 4, the plasma 116 effluent is introduced into the solution 104 through a conduit or pipe 120, so as not to subject the crystal 110 growth interface directly to the plasma 116 gas flows. The growth solution 104 becomes supersaturated with nitrogen through leakage or diffusion of plasma 116 effluent through the conduit 120 pores or channels. The interaction of the non-thermal atmospheric pressure plasma 116 with the solution 104 can be modulated by altering the configuration of the conduit 120. For example, the conduit 120 may includes pores that introduce only a portion of the non-thermal atmospheric pressure plasma to the Group-III nitride crystal's growth interface. Indeed, the conduit 120 geometry, spacing, etc., as well as separation 118 between the conduit 120 and seed 110 growth interface, can all be optimized to promote crystal 110 growth.

Variations and Modifications

Major variations pertaining to this invention involve further permutations and configurations along the lines of the preferred embodiments described above. For instance, another configuration could involve intermittent and brief submersion of a plasma source such that the disruption caused by the submerged gas flow is not sufficient to substantially affect the crystal growth rate or crystal quality.

The “conduit” or “leakage” concept could be implemented in a variety of manners and geometries. Conduits could be introduced in the form of coiled tubes, “showerheads”, etc., with varying orientations and separations between the plasma outlet and the crystal growth interface.

As noted previously, the non-thermal atmospheric pressure plasma can be generated using a variety of methods, with the preferred method being that which provides the highest concentration of the crystal component of interest, compatible with furnace design and crystal growth stability constraints.

Other modifications for the submerged plasma embodiment in particular involves secondary excitation to aid in plasma formation and stabilization, such as through introduction of sonic pulses or standing waves (so-called “sonoplasma”).

As noted above, this invention describes a process, apparatus and material for GaN bulk crystal growth utilizing non-thermal atmospheric pressure plasmas. The invention motivation and detailed description focuses on growth of GaN, but it is important to emphasize that this invention potentially pertains to growth of any compound crystal where at least one component can be incorporated into a plasma phase. For instance, growth of oxide crystals such as ZnO, YBaCuO, BaTiO₃, etc., should be possible using an oxygen-containing plasma and a suitable growth solution.

In each particular case, including that of GaN, multiple possibilities exist for flux component and exact crystal composition. Additions of In or Al to the melt, for instance, could result in alloyed crystals of InₓGa₁₋ₓN or AlₓGa₁₋ₓN. Possible flux components in the case of GaN growth include Sn, Na, K, Li, Ca, etc., as well as ternary and quaternary combinations. Modification of the electronic structure of GaN, or doping, can be accomplished through inclusion of small amounts of donor or acceptor elements, such as Si, Mg, C, Be, etc., in the growth solution.

This invention primarily describes a process for bulk crystal growth, but if no seed is introduced, the same process will result in growth of many small crystals simultaneously. For instance, the process described here can be used to grow many small crystals of GaN simultaneously (polyGaN), which can then be used as a feedstock material for other processes such as ammonothermal bulk crystal growth. This process can also be adapted to grow large-area films (multi or single crystalline) of varying thickness for use in applications such as solar cells or detectors.

Advantages and Benefits

This invention describes atmospheric pressure plasma sources, whereas previous examples employed sub-atmospheric plasmas which require complicated reactor designs and produced lower active species concentrations.

In configuration B of the preferred embodiments, bulk crystal growth using a submerged non-thermal atmospheric pressure plasma (SNAP) source is described. This is a novel description and offers several advantages over state-of-the art plasma-assisted crystal growth techniques. These advantages include low overall gas flow rates leading to minimal disruption of the growth solution as well as the ability to modify and adjust the orientation of the plasma source with respect to the crystal growth interface.

The invention disclosed herein describes crystal growth where the driving force is through supersaturation of one crystal component supplied externally through a plasma source. This means crystal growth can be accomplished with a minimal or no temperature gradient, reducing thermal stresses on the crystal and producing high quality, low-defect material.

Since the driving force for crystal growth is externally controlled, crystal constituents can be introduced at a constant concentration over a large growth area with little to no depletion due to surface diffusion effects. Combined with isothermal conditions, large-area bulk crystal growth should be more readily achievable than other bulk crystal growth methods.

Since no ammonia is used in the crystal growth process (as opposed to ammonothermal and HVPE methods), it may be possible to grow GaN crystals with relatively low levels of hydrogen. If this is the case, introduction of Mg to the solution and suppression of donor-type defects (O impurities, nitrogen vacancies) could result in high concentrations of activated acceptors in the resulting bulk crystals (or polyGaN), rendering them p-type doped.

Nomenclature

The terms “Group-III nitride” or “III-nitride” or “nitride” as used herein refer to any composition or material related to (Al,B,Ga,In)N semiconductors having the formula Al_{w}BₓGa_{y}In_{z}N where 0≦w≦1, 0≦x≦1, 0≦y≦1, 0≦z≦1, and w+x+y+z=1. These terms as used herein are intended to be broadly construed to include respective nitrides of the single species, Al, B, Ga, and In, as well as binary, ternary and quaternary compositions of such Group III metal species. Accordingly, these terms include, but are not limited to, the compounds of AlN, GaN, InN, AlGaN, AlInN, InGaN, and AlGaInN. When two or more of the (Al,B,Ga,In)N component species are present, all possible compositions, including stoichiometric proportions as well as off-stoichiometric proportions (with respect to the relative mole fractions present of each of the (Al,B,Ga,In)N component species that are present in the composition), can be employed within the broad scope of this invention. Further, compositions and materials within the scope of the invention may further include quantities of dopants and/or other impurity materials and/or other inclusional materials.

This invention also covers the selection of particular crystal terminations and polarities of Group-III nitrides. Many Group-III nitride devices are grown along a polar orientation, namely a c-plane {0001} of the crystal, although this results in an undesirable quantum-confined Stark effect (QCSE), due to the existence of strong piezoelectric and spontaneous polarizations. One approach to decreasing polarization effects in Group-III nitride devices is to grow the devices along nonpolar or semipolar orientations of the crystal.

The term “nonpolar” includes the {11-20} planes, known collectively as a-planes, and the {10-10} planes, known collectively as m-planes. Such planes contain equal numbers of Group-III and Nitrogen atoms per plane and are charge-neutral. Subsequent nonpolar layers are equivalent to one another, so the bulk crystal will not be polarized along the growth direction.

The term “semipolar” can be used to refer to any plane that cannot be classified as c-plane, a-plane, or m-plane. In crystallographic terms, a semipolar plane would be any plane that has at least two nonzero h, i, or k Miller indices and a nonzero 1 Miller index. Subsequent semipolar layers are equivalent to one another, so the crystal will have reduced polarization along the growth direction.

When identifying orientations using Miller indices, the use of braces, { }, denotes a set of symmetry-equivalent planes, which are represented by the use of parentheses, ( ). The use of brackets, [ ], denotes a direction, while the use of brackets, < >, denotes a set of symmetry-equivalent directions.

### REFERENCES

The following patents are incorporated by reference herein:
1. U.S. Pat. No. 7,097,707, issued Aug. 29, 2006, to Xu et al., and entitled “GAN BOULE GROWN FROM LIQUID MELT USING GAN SEED WAFERS.”
2. U.S. Pat. No. 7,288,151, issued Oct. 30, 2007, to Sasaki et al., and entitled “METHOD OF MANUFACTURING GROUP-III NITRIDE CRYSTAL.”

### CONCLUSION

This concludes the description of the preferred embodiment of the present invention.

The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for growing a compound crystal, comprising:
growing a Group-III nitride crystal using a flux-based growth, wherein the flux-based growth includes:
(1) a solution comprised of at least one Group-III metal contained within a vessel, wherein the solution and one or more surfaces of a seed upon which the Group-III nitride crystal is grown are brought into contact; and
(2) a source of at least one component for the growth of the Group-III nitride crystal is a non-thermal atmospheric pressure plasma introduced to the vessel.

2. The method of claim 1, wherein the plasma is operated at a pressure between 0.5 atmospheres and 3 atmospheres.

3. The method of claim 1, wherein the non-thermal atmospheric pressure plasma is the source for nitrogen at atmospheric pressure.

4. The method of claim 1, wherein the non-thermal atmospheric pressure plasma is one or more directed streams in communication with the solution.

5. The method of claim 1, wherein the non-thermal atmospheric pressure plasma is incident above a surface of the solution.

6. The method of claim 1, wherein the non-thermal atmospheric pressure plasma is submerged within the solution.

7. The method of claim 1, wherein the non-thermal atmospheric pressure plasma is introduced within the solution by a conduit.

8. The method of claim 7, wherein the conduit includes pores that introduce only a portion of the non-thermal atmospheric pressure plasma to the Group-III nitride crystal's growth interface.

9. The method of claim 7, wherein the non-thermal atmospheric pressure plasma's interaction with the solution is modulated by altering the conduit.

10. The method of claim 1, wherein the non-thermal atmospheric pressure plasma and the Group-III nitride crystal's growth interface are separated by a distance that promotes the Group-III nitride crystal's growth while preventing disruption of the Group-III nitride crystal's growth interface.

11. The method of claim 1, wherein the solution comprises an electrode for a source of the non-thermal atmospheric pressure plasma.

12. A crystal grown by the method of claim 1.

13. An apparatus for growing a compound crystal, comprising:
a reactor for growing a Group-III nitride crystal using a flux-based growth, wherein the flux-based growth method includes:
(1) a solution comprised of at least one Group-III metal contained within the reactor, wherein the solution and one or more surfaces of a seed upon which the Group-III nitride crystal is grown are brought into contact; and
(2) a source of at least one component for the growth of the Group-III nitride crystal is a non-thermal atmospheric pressure plasma introduced to the reactor.

14. The apparatus of claim 13, wherein the plasma is operated at a pressure between 0.5 atmospheres and 3 atmospheres.

15. The apparatus of claim 13, wherein the non-thermal atmospheric pressure plasma is the source for nitrogen at atmospheric pressure.

16. The apparatus of claim 13, wherein the non-thermal atmospheric pressure plasma is one or more directed streams in communication with the solution.

17. The apparatus of claim 13, wherein the non-thermal atmospheric pressure plasma is incident above a surface of the solution.

18. The apparatus of claim 13, wherein the non-thermal atmospheric pressure plasma is submerged within the solution.

19. The apparatus of claim 13, wherein the non-thermal atmospheric pressure plasma is introduced within the solution by a conduit.

20. The apparatus of claim 19, wherein the conduit includes pores that introduce only a portion of the non-thermal atmospheric pressure plasma to the Group-III nitride crystal's growth interface.

21. The apparatus of claim 19, wherein the non-thermal atmospheric pressure plasma's interaction with the solution is modulated by altering the conduit.

22. The apparatus of claim 13, wherein the non-thermal atmospheric pressure plasma and the Group-III nitride crystal's growth interface are separated by a distance that promotes the Group-III nitride crystal's growth while preventing disruption of the Group-III nitride crystal's growth interface.

23. The apparatus of claim 13, wherein the solution comprises an electrode for a source of the non-thermal atmospheric pressure plasma.
